(19) United States
(12) Patent Application Publication
(10) Pub. No.: US 2025/0071904 A1
(43) Pub. Date: Feb. 27, 2025

(54) INTEGRATED COIL MODULE

(71) Applicant: TAI-TECH ADVANCED ELECTRONICS CO., LTD., Taoyuan City (TW)

(72) Inventors: Ming-Yen Hsieh, Taoyuan City (TW); Pao-Lin Shen, Taoyuan City (TW); Hsiang-Chung Yang, Taoyuan City (TW); Wei-Hsuan Lo, Taoyuan City (TW)

(21) Appl. No.: 18/452,585

(22) Filed: Aug. 21, 2023

(51) Int. Cl. H05K 1/18; H01F 27/29; H01F 27/34

(52) U.S. Cl. CPC H05K 1/181; H01F 27/292; H01F 27/346; H05K 2201/1003; H05K 2201/10522; H05K 2201/1056

(57) ABSTRACT

An integrated coil module includes: a substrate; a plurality of inductor elements arranged on the substrate with a spacing distance between adjacent inductor elements, the inductor elements each including an iron core, first and second coils wound on the iron core, first and second flanges at two sides of the iron core, and a third flange arranged on the iron core and between the first and second flanges, the first flange including first and second electrodes, the second flange including third and fourth electrodes, the third flange including fifth and sixth electrodes; and a plate arranged atop the plurality of inductor elements to cover the inductor elements. As such, the plurality of inductor elements are integrated together as a one-piece structure to thereby simplify the SMT manufacturing process and shorten the spacing distance between the inductor elements so as to reduce the area of the substrate occupied thereby.

### BACKGROUND OF THE INVENTION

### (a) Technical Field of the Invention

The present invention relates generally to a coil module, and more particularly to an integrated coil module.

### (b) Description of the Prior Art

As shown in FIG. 1, known inductor elements are often arranged, in multicity, on a substrate 10, and each of the inductor elements 20 is provided with a plate 30 on a top thereof. This makes surface mount technology (SMT) processing tedious and complicated. And, it is hard to reduce the spacing distance between adjacent inductor elements 20.

### SUMMARY OF THE INVENTION

In view of the above problems, the present invention aims to provide an integrated coil module.

To achieve the above objective, the present invention provides an integrated coil module, which comprises:
a substrate;
a plurality of inductor elements, the inductor elements being arranged on the substrate, a spacing distance being formed between adjacent ones of the inductor elements, the inductor elements each comprising an iron core, a first coil and a second coil wound on the iron core, a first flange and a second flange arranged at two sides of the iron core, a third flange arranged between the first flange and the second flange, the third flange being arranged on the iron core, the first flange comprising a the first electrode and a second electrode mounted thereon, the second flange comprising a third electrode and a fourth electrode mounted thereon, the third flange comprising a fifth electrode and a sixth electrode mounted thereon, the first coil being electrically connected to the first electrode, the sixth electrode, and the fourth electrode, the second coil being electrically connected to the second electrode, the fifth electrode, and the third electrode; and
a plate, the plate being arranged atop the plurality of inductor elements to cover the inductor elements, the plate having a length that is equal to a sum of lengths of the plurality of inductor elements and the spacing distance between every adjacent ones of the inductor elements.

Based on the above arrangement, the present invention allows a plurality of inductor elements 2 to be integrated together as a one-piece arrangement to thereby simplify a surface mount technology (SMT) manufacturing process and also to have the spacing distance between adjacent ones of the inductor elements shortened to effectively reduce the area occupied thereby on a substrate.

### BRIEF DESCRIPTION OF THE DRAWINGS

FIG. 1 is a schematic view showing prior art.

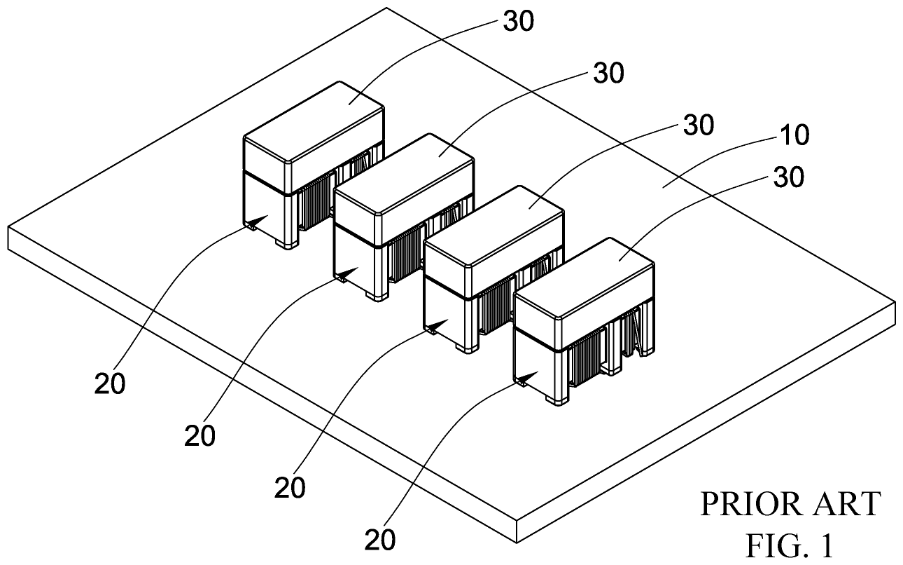

FIG. 2 is a perspective view of the present invention in an assembled form.

FIG. 3 is an exploded view of the present invention.

FIG. 4 is a bottom view of an inductor element of the present invention.

FIG. 5 is a schematic view showing arrangement of spacer boards between the inductor elements of the present invention.

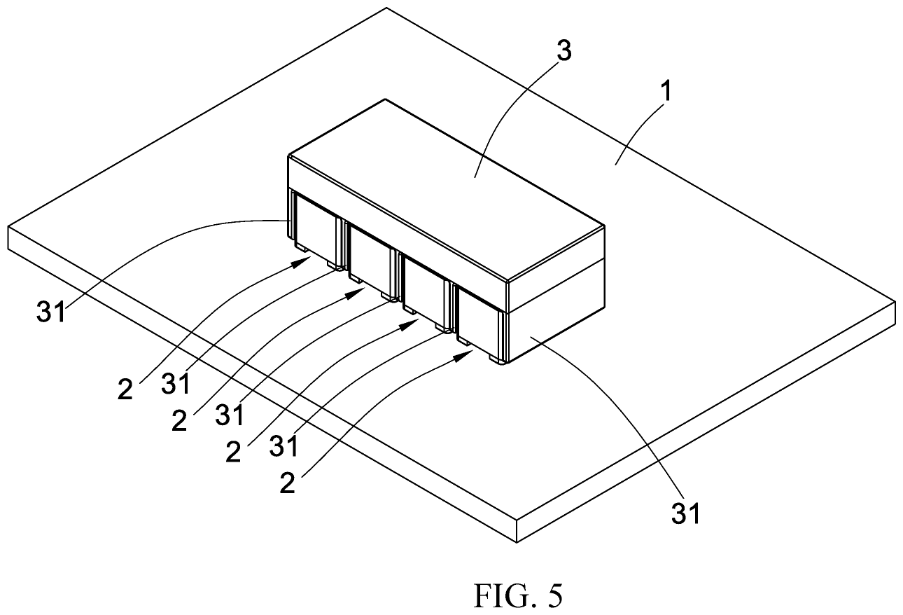

FIG. 6 is a perspective view showing a plate and the spacer boards integrally formed together as a one piece structure according to the present invention.

### DETAILED DESCRIPTION OF THE PREFERRED EMBODIMENTS

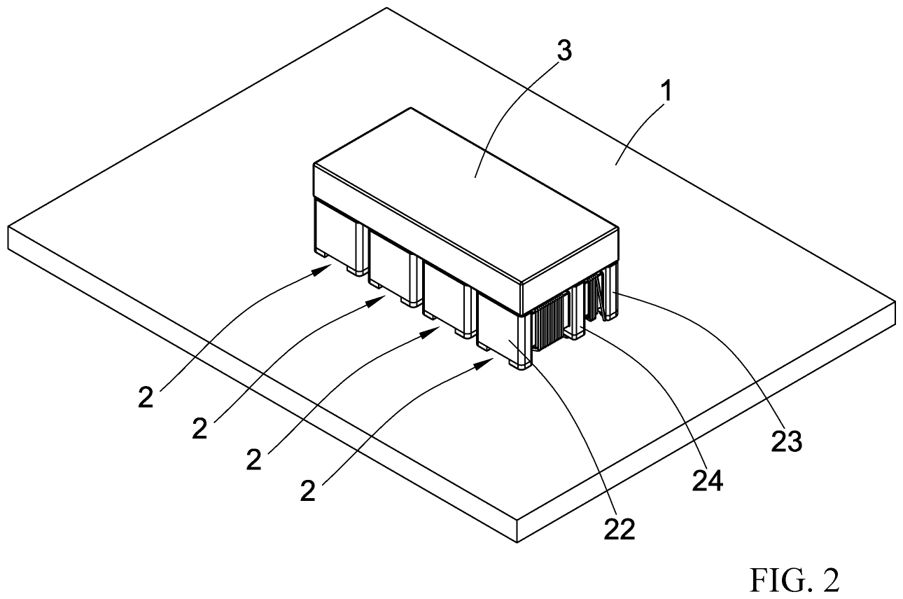

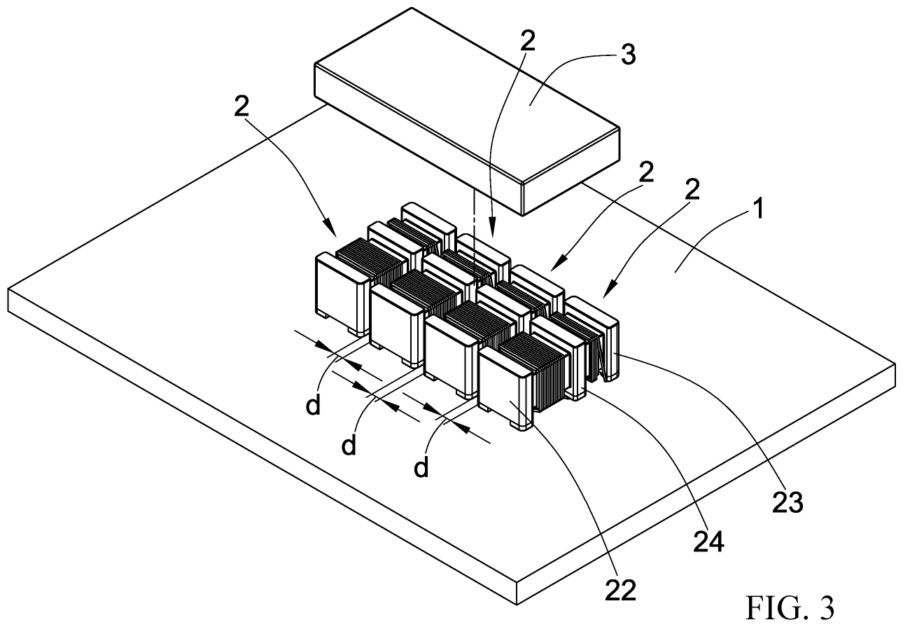

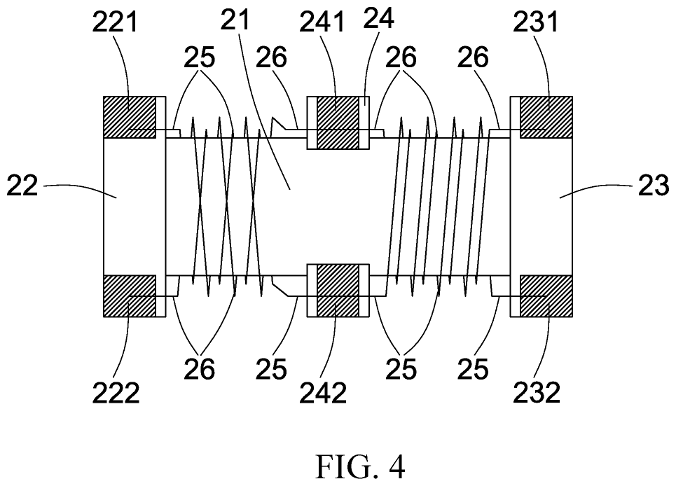

Referring to FIGS. 2, 3, and 4, an integrated coil module comprises:
a substrate 1;
a plurality of inductor elements 2, wherein the inductor elements 2 are arranged on the substrate 1, and a spacing distance d is formed between adjacent ones of the inductor elements 2; each of the inductor elements 2 comprises an iron core 21, a first coil 25 and a second coil 26 wound around the iron core 21, a first flange 22 and a second flange 23 arranged at two sides of the iron core 21 and a third flange 24 arranged between the first flange 22 and the second flange 23, wherein the third flange 24 is arranged on the iron core 21; the first flange 22 is provided with a first electrode 221 and a second electrode 222 mounted thereon; the second flange 23 is provided with a third electrode 231 and a fourth electrode 232 mounted thereon; the third flange 24 is provided with a fifth electrode 241 and a sixth electrode 242 mounted thereon; and the first coil 25 is electrically connected (soldered) to the first electrode 221, the sixth electrode 242, and the fourth electrode 232, and the second coil 26 is electrically connected (soldered) to the second electrode 222, the fifth electrode 241, and the third electrode 231; and
a plate 3, wherein the plate 3 is arranged atop the plurality of inductor elements 2 to cover the inductor elements 2, and the plate 3 has a length that is equal to a sum of lengths of the plurality of inductor elements 2 and the spacing distance d between every two adjacent ones of the inductor elements 2.

The plate 3 comprises a magnetic metal.

The substrate 1 comprises a circuit board.

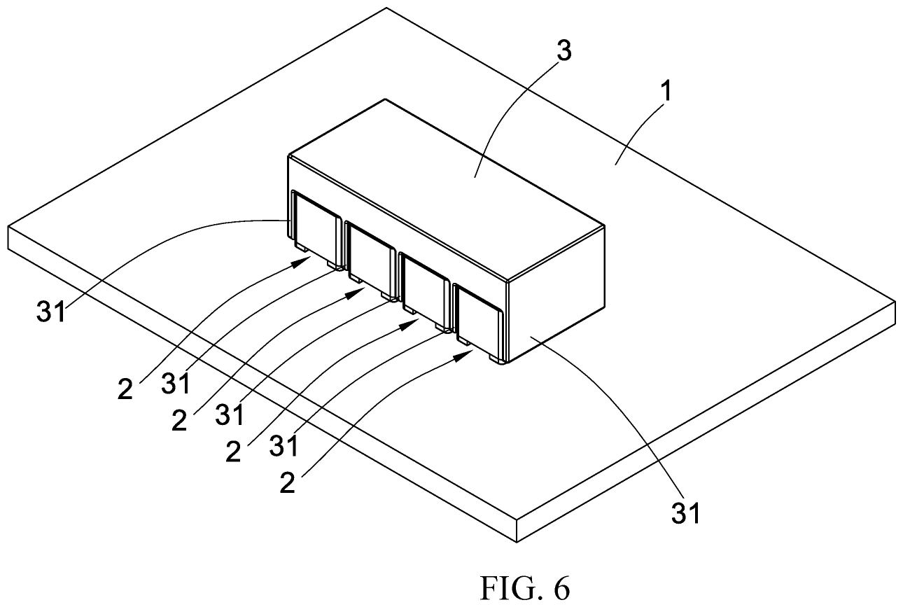

Referring to FIG. 6, spacer boards 31 are arranged between adjacent ones of the inductor elements 2. The spacer boards 31 space the inductor elements 2 from each other to prevent mutual interference among the inductor elements 2 due to magnetic leakage.

The spacer boards 31 comprise a magnetic metal.

Referring to FIG. 7, the spacer boards 31 can be integrally formed with the plate 3 as a one-piece structure.

Based on the above arrangement, the present invention provides the plate 3 to integrate the plurality of inductor elements 2 together as a one-piece arrangement to thereby simplify a surface mount technology (SMT) manufacturing process and also to have the spacing distance between adjacent ones of the inductor elements 2 shortened to effectively reduce an area occupied thereby on the substrate 1, and further, the arrangement of the spacer boards 31 helps prevent mutual interference among the inductor elements 2 resulting from magnetic leakage.

I claim:

1. An integrated coil module, comprising:
a substrate;
a plurality of inductor elements, the inductor elements being arranged on the substrate, a spacing distance being formed between adjacent ones of the inductor elements, the inductor elements each comprising an iron core, a first coil and a second coil wound on the iron core, a first flange and a second flange arranged at two sides of the iron core, a third flange arranged between the first flange and the second flange, the third flange being arranged on the iron core, the first flange comprising a the first electrode and a second electrode mounted thereon, the second flange comprising a third electrode and a fourth electrode mounted thereon, the third flange comprising a fifth electrode and a sixth electrode mounted thereon, the first coil being electrically connected to the first electrode, the sixth electrode, and the fourth electrode, the second coil being electrically connected to the second electrode, the fifth electrode, and the third electrode; and
a plate, the plate being arranged atop the plurality of inductor elements to cover the inductor elements, the plate having a length that is equal to a sum of lengths of the plurality of inductor elements and the spacing distance between every adjacent ones of the inductor elements

2. The integrated coil module according to claim 1, wherein the plate comprises a magnetic metal.

3. The integrated coil module according to claim 1, wherein spacer boards are arranged between the inductor elements.

4. The integrated coil module according to claim 3, wherein the spacer boards comprise a magnetic metal.

5. The integrated coil module according to claim 3, wherein the spacer boards are integrally formed with the plate as a one-piece structure.
